(19) United States
(12) Patent Application Publication
(10) Pub. No.: US 2026/0173921 A1
(43) Pub. Date: Jun. 18, 2026

(54) WAFER-SCALE MULTI-CHIP INTEGRATED CIRCUIT PACKAGES HAVING BRIDGELESS SUBSTRATES

(71) Applicant: Volantis Semiconductor Inc., Portland, OR (US)

(72) Inventor: Tapabrata Ghosh, Oakland, CA (US)

(73) Assignee: Volantis Semiconductor Inc., Portland, OR (US)

(21) Appl. No.: 18/981,265

(22) Filed: Dec. 13, 2024

(51) Int. Cl. H01L 23/538; H01L 21/48; H01L 25/07

(52) U.S. Cl. CPC H10W 70/65; H10W 70/093; H10W 70/611; H10W 70/635; H10W 90/00

(57) ABSTRACT

A multi-reticle IC structure comprising a substrate comprising a surface and an array of lithographically-patterned regions distributed on the surface, wherein ones of the lithographically-patterned regions comprise two or more domains. Each of the two or more domains comprise one of one or more metallization structure patterns and is interconnected to at least one adjacent domain by a plurality of embedded interconnects coupled to a first metallization structure pattern within the at least one adjacent domain. The plurality of embedded interconnects extends laterally between adjacent domains of the two or more domains. The lithographically-patterned regions includes first and second lithographically-patterned regions, wherein an IC die of a plurality of IC dies is bonded to at least a first domain of the two or more domains in the first lithographically-patterned region and to a second domain of the two or more domains in the second lithographically-patterned region, wherein the second domain is adjacent to the first domain.

### BACKGROUND

In recent years, the microelectronics industry has seen a resurgence of interest in advance packaging technologies. In these systems, it is generally desirable to maximize the density of wire achievable, as this allows for multiple parallel connections, resulting in more aggregate bandwidth. Along with this demand, there is also increased interest in growing the total silicon area that can be packaged together at the same time. Growing the total silicon area to increase compute power presents challenges.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIG. 1 illustrates a schematic of a portion of a wafer-scale integrated circuit (WSIC) assembly showing adjacent reticles and overlapped by an integrated circuit (IC) chip, in accordance with at least one example.

FIG. 2 illustrates a schematic view of a larger portion of the WSIC assembly shown in FIG. 1, comprising an array of IC chips interpenetrating an array of reticles on a substrate, in accordance with at least one example.

FIG. 3 illustrates a schematic of a cross section of a WSIC with attached IC chips to show interconnections between IC chips with horizontal interconnects, in accordance with at least one example.

FIG. 4A illustrates a schematic view of a WSIC exhibiting a hexagonal reticle geometry, in accordance with at least one example.

FIG. 4B illustrates a schematic view of the WSIC in FIG. 4A, showing organizational details, in accordance with at least one example.

FIG. 4C illustrates a schematic view of a triangular reticle, showing three domains in accordance with at least one example.

FIG. 4D illustrates a schematic view of an additional triangular reticle that may be combined with the triangular reticle shown in FIG. 4C, in accordance with at least one example.

FIG. 4E illustrates a schematic view of a hexagonal region of the WSIC illustrated in FIG. 4A, in accordance with at least one example.

FIG. 5 illustrates a schematic view of multiple metallization patterns appearing in different reticle sectors, in accordance with at least one example.

FIGS. 6A-6D illustrate a sequence of structures depicting the evolution of an exemplary assembly process flow to make a multi-chip WSIC, in accordance with some examples.

FIG. 7 illustrates a schematic view of a final stage of assembly of WSIC, in accordance with at least one example.

FIG. 8 illustrates a process flow diagram recapping the process flow depicted in FIGS. 6A-6D, in accordance with at least one example.

### DETAILED DESCRIPTION

Silicon interconnect “fabric” technologies may replace traditional organic printed circuit boards to allow far more compact and powerful computing devices than can be imagined with the current paradigm. These silicon “fabric” substrates are based on large wafer-scale silicon wafer-based interposer technologies that compactly weave together fleets (e.g., up to thousands) of unpackaged IC dies (e.g., chiplets or dielets) directly onto wafer-sized silicon substrates. Because silicon substrates, in contrast to conventional organic substrates such as printed circuit boards (PCBs), can support very high-density routing architectures, it is possible to incorporate highly parallelized, high input/output (I/O) bandwidth interconnect routing onto the silicon substrate. High-bandwidth memory (HBM) and compute system integration is an example of a target application that is increasingly important and will be facilitated by silicon fabric technologies, given current projections for graphical GPU and artificial intelligence (AI) demand.

Current IC packaging using organic substrate technologies relies heavily on system-on-chip (SoC) IC architectures to achieve I/O high bandwidths. SoC packages are larger, complicated, and more difficult to fabricate than silicon fabric-based chiplet integration, due in part to the need for adding redistribution layer metallization, fanout, etc., for solder bumping on the SoC pinouts that is adapted to match PCB substrate interconnect pitches (typically 500 μm pad pitch). Silicon fabric technologies enable the bypassing of SoCs in favor of simpler direct wafer-scale assemblies of chiplets that can be readily matched to high-density pad pitches (e.g., 10 to 50 microns). This approach can drastically reduce the manufacturing costs of HBM and other systems, for example. In contrast, organic PCB substrates cannot support high density interconnect architectures, and as such are limited in bandwidth. Only a limited number of smaller conventional-sized chip packages onto multiple printed circuit boards or large mother boards. A fabric-type substrate allows many chiplets or chiplet dies to be integrated into a wafer-scale package, far more than can be realized in the same footprint using PCB substrates. There are a wide variety of methods to produce muti-chip packages to connect multiple chips together.

Wafer-scale systems are several times larger than the limit size of a chip, typically defined by a reticle frame, which is approximately 33 mm×26 mm (858 mm²). The reticle field limit is the maximum optical aperture limit for transferring a mask pattern for a single chip. While the advantages of abandoning organic PCB substrates in favor of wafer-scale silicon are numerous, these very large-scale packages are challenging to build. For example, thermal and mechanical challenges that may be negligible at conventional package scale may no longer be negligible at wafer scale. In addition, current commercial wafer-scale systems may use strategies such as reticle stitching or bridge them using embedded bridge dies. These architectural strategies increase the cost of manufacture for silicon fabrics, yet do not solve thermal and mechanical challenges posed by the increased size. Several solutions have been proposed or implemented in the industry to overcome and exceed the reticle limit. However, these approaches have their own challenges that have not been addressed.

Disclosed herein are embodiments of a 2.5D wafer-scale integrated circuit (WSIC) for packaging, such as a large-scale interposer, comprising a multiple reticle array and an offset array of integrated circuit (IC) chips, such as a compute die array, that are bonded to the reticles on the WSIC in a staggered configuration. Here, individual IC chips are not entirely enclosed within the scribe lines (boundaries) of any individual reticle. Rather, individual IC chips straddle reticles, crossing over scribe lines. An individual IC chip thus shares interconnect pads in a reticle with other IC dies, being bonded to interconnects located in a particular portion of the reticle. For example, an individual IC chip may overlap four adjacent reticles, being bonded to interconnect pads in a different quadrant (e.g., lower right, lower left, upper right, and upper left) within each adjacent reticle. Here, multiple adjacent IC chips (e.g., four IC chips) may share one reticle on the WSIC, and conversely, multiple adjacent reticles (e.g., two or four reticles) may share one IC chip. where a portion of each IC chip is bonded to a specific portion of the reticle.

The specific reticle portions may be referred to herein as “quadrants” of the reticle for four-sided symmetries. In some embodiments, other geometries are considered. For example, a WSIC exhibiting hexagonal symmetry is also disclosed, whereby reticles are triangular. Regions of non-rectangular reticles that are overlapped by IC chips may be referred to as “domains”. In a broad sense, quadrants of rectangular reticles may also be considered domains of the reticle. Reticle domains (e.g., tiles, quadrants) may contain metallization patterns, for example, patterns of interconnect pads, corresponding to bonding pad distributions on the areas of the chiplets that are to be attached to the domains of a particular reticle. For embodiments described herein, reticles are not interconnected through the substrate, however, may be interconnected through attached chiplets that cross reticles.

In other examples of wafer-scale substrates, reticle stitching is employed for interconnecting separate reticles for enabling a chip-to-chip communications network between large numbers of chiplets attached to the wafer-scale substrate. Reticle stitching extends I/O lines from reticle to reticle, creating a network across the wafer (for example, UCLA's Silicon Interconnect Fabric (Si-IF) technology). In the Si-IF scheme, chiplets do not cross reticles but are confined to reticles, and reticle stitching enables pan-wafer networking between chiplets. However, reticle stitching requires highly accurate alignment of reticles to align fine inter reticle lines for high bandwidth I/O that are as small as 1 micron wide, with about the same pitch. With large wafers, such as 300 mm wafers, alignment and resolution problems may be compounded by the need for multiple masks as the size increases. Stepper (step and repeat) mask alignment lithography is used here to repeat reticle patterns across a wafer, necessitating highly accurate and high-resolution optics. Good overlap between fine I/O lines extending from neighboring reticles may be difficult to obtain at production scale using masks. An alternative to step and repeat mask lithography is maskless lithography, using laser writing heads to scan across wafers, however this technique uses an expensive tool, has lower resolution and low throughput and may not be suitable for large scale manufacturing.

Another enabling technology is the incorporation of bridge dies into the substrate. Bridge dies perform coupling between adjacent chiplets below the level of chiplet attachment to enable pan-wafer chip-to-chip communication (e.g., Intel's EMIB bridge die technology, TSMC's chip-on-wafer-on-substrate (CoWoS) technology or ASE's Fan-Out-Chip-on-Substrate Bridge FOCoS Bridge technology). Bridge dies are generally embedded within a polymeric laminate buildup layer or encapsulated by a polymeric overmold, creating thermal expansion differentials between organic materials and silicon (or other semiconductor), and ceramics (e.g., oxides) as well if present. These thermal differentials can cause significant warpage of the device and internal stresses both during manufacture and in end user applications, eventually leading to premature failure. It may be understood that warpage and other CTE mismatch failures due to warpage and thermal stress increase as the size of the substrate increases. Thus, large WSICs (e.g., 200 to 300 mm diameter wafers) based on current technologies noted above can incur significantly greater failure risk than smaller conventional chip packages, such as conventional SoCs, and may be impractical to manufacture and market.

The WSIC of at least one example can solve both disadvantages noted above by spanning reticles with the attached chiplets in a checkerboard fashion. Here, chiplets are not confined to individual reticles but staggered across reticles. In contrast to the current technologies, chiplets do not communicate through the substrate but by the chiplets themselves. In at least one example, chiplets in the WSIC span multiple reticles, inter-chip communication is accomplished by cross connects between each domain within a reticle. The attached chiplets themselves form inter-reticle bridges, and can transfer signals from reticle to reticle, thus enabling pan-wafer networking.

Technological advantages of the approach disclosed herein are at least two-fold. First, elimination of both reticle stitching and use of bridge dies simultaneously simplifies lithographic complexity by obviating the need to connect reticles together lithographically and eliminating complex fabrication steps of embedding bridge dies and forming redistribution layer (RDL) metallization over them to connect to chiplets above. Second, by eliminating the need for bridge dies, the introduction of heterogeneous materials into the substrate is eliminated, enabling a unified WSIC substrate based on only silicon (or other semiconductor or ceramic) to be produced. By having a unified substrate, one or few closely matched materials may be used (e.g., silicon, silicon oxides and copper, but not including solder that may be used for attaching chiplets). Accompanying warpage and thermal stress issues are mostly eliminated by fabrication of an all-silicon WSIC at large scale (for example 300 mm). These approaches thereby simplify fabrication of the WSIC substrate, increase yield and render it significantly more robust to the end user.

By staggering placement and bonding of chiplets relative to the reticle positions in a checkerboard fashion, such that the IC chips straddle adjacent reticles and are bonded to particular metallization domains of the reticles (e.g., quadrants in rectangular reticles), the reticles are electronically bridged by the internal circuitry of the IC chips bonded to them. Reticles may be coupled through the internal circuitry of the individual IC chips. Metallization patterns within the domains or quadrants of each reticle may correspond to chip interconnect pads on the bonding side of the chip that overlap the domain or quadrant.

Here, “chip” may generally refer to an integrated circuit (IC) comprising one or more semiconductor dies that is or are contained in a package. The die or dies within a chip may be a portion of a processed semiconductor wafer. The die or dies may be attached to a semiconductor substrate (e.g., a piece of silicon) or a resin-based printed circuit board.

In at least one example, chips, chiplets or dies within a family of network topologies are processors or processor cores. In at least one example, chiplets or dies within a family of network topologies function as encoders. In at least one example, encoders are a part of a communication interface of processors or processor cores, where the encoders can facilitate the transmission of signals between the processors or the processor cores via the set of principle interconnects and the set of redundant interconnects. In at least one example, chiplets or dies within a family of network topologies can be functionally similar. In at least one example, chips, chiplets or dies within a family of network topologies are functionally different from each other. In at least one example, the family of network topologies is a hierarchical topology, where an intra-group topology is not a mesh or torus, and where an inter-group topology is a mesh or torus. In at least one example, the intra-group topology is a fully-connected topology, and the inter-group topology is a mesh or torus. In at least one example, the intra-group topology is a fat-tree topology, and the inter-group topology is a mesh or torus topology.

Here, “chiplet” or “dielet” may generally refer to an Integrated Circuit (IC) or a die that is designed to operate as a part of a larger system-on-chip (SoC) architecture. Instead of creating a complete custom chip from scratch, manufacturers can use multiple chiplets or dies, each designed for specific functions, and integrate them into a single package or die. Chiplets allow for modular design, which can improve efficiency and reduce manufacturing costs. This approach also provides flexibility, as different chiplets can be combined in various configurations to meet the demands of different applications. Chiplets can provide various functions, including processing cores, memory controllers, or specific I/O functionalities. Chiplets can be used in high-performance computing and edge devices, as they enable quicker time-to-market and the ability to mix and match to create optimized solutions. Chiplets or dielets may have relatively small dimensions, for example 5 mm or less.

Here, “die” may generally refer to a single continuous piece of semiconductor material (e.g. silicon) where transistors or other components which make up a processor core may reside. Multi-core processors may have two or more processors on a single die, but alternatively, the two or more processors may be provided on two or more respective dies. In at least one example, dies are of the same size and functionality i.e., symmetric cores. In at least one example, dies are asymmetric. For example, some dies have different size and/or function than other dies.

Here, “interconnects” may generally refer to electrical wiring either of or in integrated circuits that facilitates communication between different components, e.g., chiplets, dielets, dies, nodes, processors, circuits, or functional blocks. An interconnect may be a communication link between two or more components or nodes. Interconnects can enable the transfer of signals, data, and power across a system, ensuring that components can effectively work together. The configuration of interconnects significantly influences the performance, speed, and reliability of the overall circuit. Interconnects can include conduction paths such as a fabric, passive or active components, wires, vias, waveguides, fiber optics, etc.

Here, “wafer-scale integrated circuit” may generally refer to a multi-chip or chiplet device that employs a whole wafer as a substrate.

In the following description, numerous details are discussed to provide a more thorough explanation of examples of the present disclosure. It will be apparent, however, to one skilled in the art, that examples of the present disclosure may be practiced without these specific details. In other instances, well-known structures and devices are shown in block diagram form, rather than in detail, to avoid obscuring examples of the present disclosure.

Note that in the corresponding drawings of the examples, signals are represented with lines. Some lines may be thicker, to indicate multiple constituent signal paths, and/or have arrows at one or more ends, to indicate primary information flow direction. Such indications are not intended to be limiting. Rather, the lines are used in connection with one or more exemplary examples to facilitate easier understanding of a circuit or a logical unit. Any represented signal, as dictated by design needs or preferences, may actually comprise one or more signals that may travel in either direction, and may be implemented with any suitable type of signal scheme, particularly those communication schemes described herein.

It is pointed out that those elements of the figures having the same reference numbers (or names) as the elements of any other figure can operate or function in any manner like that described but are not limited to such.

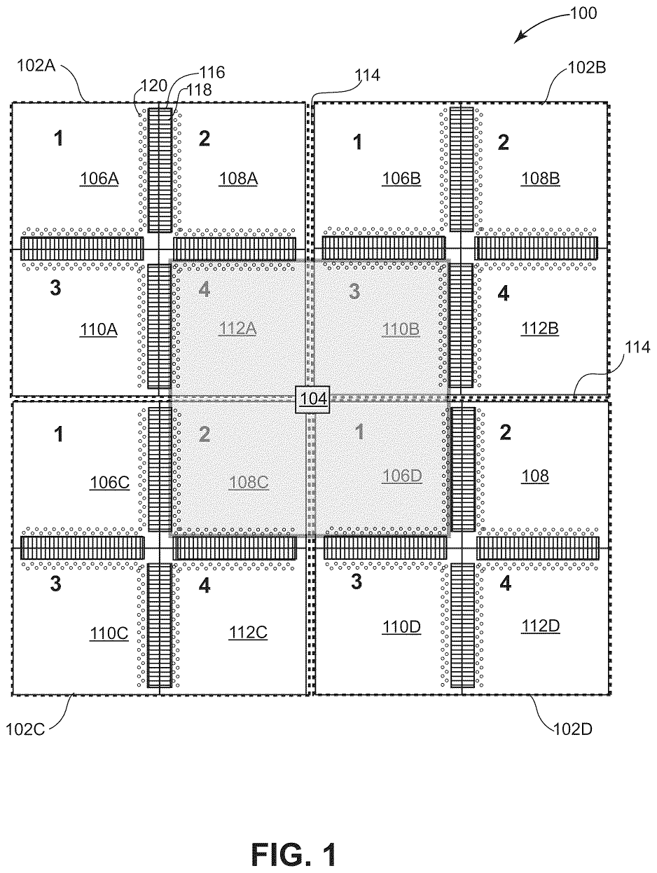

FIG. 1 illustrates a schematic of a portion of a wafer-scale integrated circuit (WSIC) 100 having reticles 102A, 102B, 102C, and 102D that are overlapped by integrated circuit (IC) chiplet 104, shown shaded in light grey, in accordance with at least one example. The shading of die 104 is semitransparent to allow a view of numbers and structures that are on the portion of the surface of WSIC 100 lying below die 104. The portion WSIC 100 shown in FIG. 1 comprises an array of four reticle fields, 106A-D, 108A-D, 110A-D, and 112A-D that contain metallization patterns (not shown) comprising surface and buried interconnect traces and pads on the surface of WSIC 100. While reticle fields may be identical, each reticle field is labeled 102A, 102B, 102C and 102D to distinguish one from the other to aid description. Individual reticle fields 102A-D are delineated by the dashed squares on the surface of WSIC 100. In some examples, reticle fields 102A-D are divided into four adjacent quadrants labelled 106A-D, 108A-D, 110A-D and 112A-D. Quadrants are also labeled by numbers 1, 2, 3, and 4 for ease of identification. In some examples, reticle fields 102A-102D are identical. Chiplet 104 is placed at the center of the view and is shaded in light grey for aid of identification. The shading is partially transparent to enable viewing of indicators below the die. Chiplet 104 spans four quadrants labelled 106D, 108C, 110B and 112A. Each of these quadrants belongs to a separate (corresponding) reticle field 102D, 102C, 102B and 102A, respectively.

Between reticle fields are scribe regions 114 extending around boundary perimeters of each reticle 102A-D. Within scribe regions 114, no trans-reticle interconnections cross scribe regions 114 to interconnect metallization in adjacent reticles. Quadrants are electrically coupled only within a reticle field. As an example, within reticle field 102A, quadrants 106A, 108A, 110A, and 112A are electrically coupled to one another through interconnect zones 116. Thus, reticle metallization is confined to individual reticle fields. On WSIC 100, metallization in any reticle field is not coupled to metallization in adjacent reticle fields. For example, reticle fields 102A-D are not interconnected by reticle stitching, a practice for manufacture of wafer-level interposers and multi-chip substrates currently employed by some fabricators. Within a reticle field, metallization patterns may be identical or different between quadrants. For example, metallization patterns within reticle field 102A may be different in each of quadrants 106A, 108A, 110A, and 112A. The same is true for reticle fields 102B, 102C, and 102D. In some examples, the same metallization patterns may be repeated from reticle field to reticle field by stepper lithography processes.

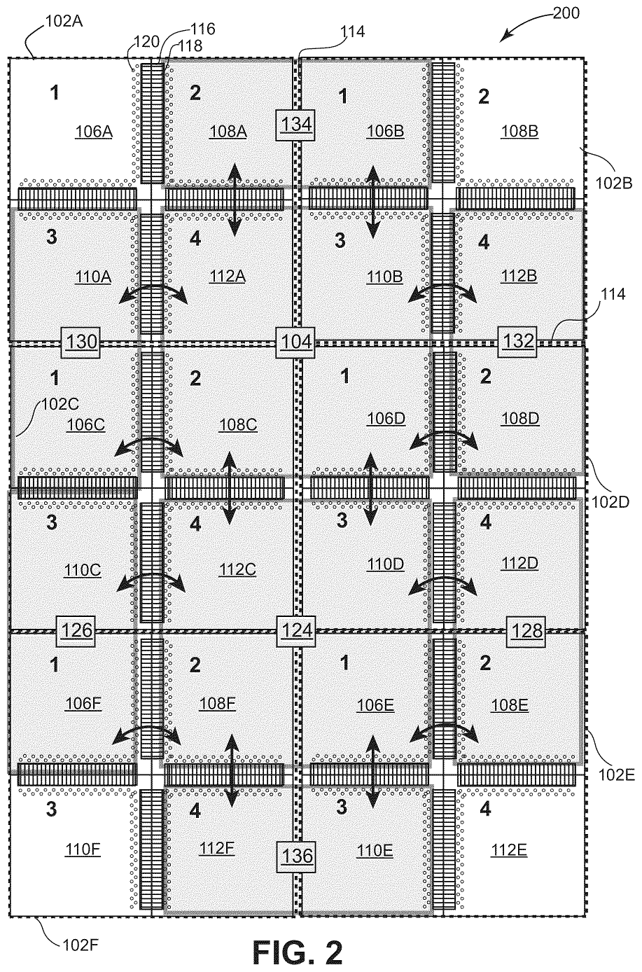

In some examples, interconnect zones 116 comprise horizontal traces 118 that span adjacent quadrants 102. The individual interconnect wires may be surface traces, buried traces, or a combination of the two, as shown in FIG. 2. The interconnect wires couple to metallization within each quadrant. In at least one example, interconnect wires may couple vertically extending through-substrate vias (TSVs), which may terminate at interconnect pads 120. Chiplet 104 has sufficient length and width extending in both x and y dimensions to substantially overlap four quadrants and may be bonded to interconnect pads 118 that are in those four quadrants, whereby each quadrant of the four quadrants within a different reticle field. For example, chiplet 104 overlaps quadrant 106D from reticle field 102D, quadrant 108C from reticle field 102C, quadrant 110B from reticle field 102B and quadrant 112A from reticle field 102A. In at least one example, quadrants 112A, 110B, 108C, and 106D may be bridged by internal circuitry wiring within chiplet 104. Thus, metallization for chiplet 104 is distributed in adjacent reticle fields, and not confined within a particular reticle field. The latter configuration is a more conventional standard, where one or more chips are generally entirely bound within a reticle. Here, chips extend over reticle boundaries defined by scribe lines and are bound to interconnect pads in adjacent reticles.

High bandwidth I/O routing may not extend between reticles. Any routing shared by adjacent reticles may include power routing, for example, but smaller high bandwidth I/O wires may not cross reticle boundaries. Having high bandwidth I/O wiring cross reticle boundaries would require reticle stitching or maskless lithography, for example. These methods are more difficult to implement successfully, and if implemented can increase manufacturing complexity, and thereby, cost. By eliminating the need for reticle stitching or maskless lithography to produce the substrates comprising isolated reticles as described herein, manufacturing costs may be significantly reduced.

In a completed assembly, chips 104 may be configured into an array that is offset from a reticle field array on WSIC 100, whereby the chip array is shifted by half a reticle width and half a reticle length (x and y), such that any chip in the array overlaps four quadrants from four adjacent reticle fields. Thus, chips in the chip array span scribe regions 114 separating four adjacent reticles, as noted earlier.

In some examples, within each reticle field there are four interconnect zones 116 that enable communication between quadrants within the reticles. It is to be understood that quadrants in adjacent reticles are not coupled to one another through on-substrate wiring, but may be interconnected through on-chip wiring, as discussed below. The interconnect zones 116 may comprise a plurality of small (e.g., L/S 5 microns or less) signal carrying I/O wires and enable electronic communication between quadrants within a reticle field, such as between quadrants 106A-112A within reticle field 102A.

In some examples, interconnect zones 111 comprise horizontal wire traces 118, which may be formed on the surface of WSIC 100 or embedded below it. For buried interconnects, horizontal wire traces 118 may be coupled to interconnect pads 120 through TSVs. Surface interconnects may be directly connected to interconnect pads 120. Thus, adjacent chips, each spanning multiple reticles, are coupled together through the substrate by horizontal wire traces 118 in interconnect zones 116 that couple together the metallization in adjacent quadrants within a reticle field.

FIG. 2 illustrates a schematic view of a partial wafer-scale multichip assembly, WSIC 200, comprising multiple adjacent IC chips attached to interconnect pads 120 contributed from adjacent reticle fields. Chiplet 104 is centered in the portion of the chiplet array shown, and is immediately adjacent to chiplets 124, 130, 132, and 134. While the chips are numbered individually, they may be identical. For example, chiplets 104, 124, 130, 132 and 134 may all comprise DRAM memory. In other examples, some or all of these chips may have different functions. The individual numbering of chiplets and reticle fields is for purposes of description only. The array of chiplets is further extended to include chiplets 126, 128, and 134, immediately adjacent to chiplet 124. Arrows show bridging between adjacent chiplets that occurs through interconnect zones 116, where interconnect zones 116 couple adjacent quadrants within each reticle field. Thus, as four reticle quadrants may be shared by a single chiplet (e.g., chiplet 104 in FIG. 1), a single reticle (e.g., reticle field 102C) shares four chiplets (e.g., chiplets 104, 124, 126, and 130), each chiplet overlapping one of the quadrants (e.g., quadrants 108C, 112C, 110C, and 106C, respectively) within a reticle field. The alphanumeric reference indicators (e.g., 108C) of the individual quadrants in the figure is to identify quadrants belonging to particular reticle fields, which have the same alphabetic character in their reference indicators (e.g., 102C). Arrows indicate that adjacent chiplets are bridge-coupled through horizontal wire traces 120. Again, no trans-reticle wiring is included in WSIC 200 (and WSIC 100) to couple adjacent reticle fields, as these are produced by stepping a reticle pattern across WSIC 200 without stitching individual reticles together using extra-reticle trace wiring (e.g., reticle stitching).

By design, in at least one example, WSIC 200 may not include buried or embedded bridge dies, such as is the case for multi-die interconnect bridge (EMIB) and equivalent systems to interconnect individual chiplets attached to the WSIC. Embedded bridge dies may introduce significant mismatch of constants of thermal expansion (CTEs) of materials into a wafer-scale multichip IC or interposer. For example, polymer buildup layer technologies (e.g., BBUL, bumpless build-up layer packaging technology) may be used to construct substrates with embedded bridge dies on a wafer-scale substrate using polymer laminate layering built up around the bridge dies. The bridge dies themselves are generally made as semiconductor monolithic dies, from silicon, for example, that has a much smaller CTE than polymer build up layers. Thus, as dies heat up during use, thermal expansion mismatches between silicon dies and surrounding polymer may disrupt the integrity of a wafer-scale embedded die construct. On smaller scales, for instance for small chip packaging, thermal expansion mismatches may be insignificant enough to not be a consideration. However, for wafer scale systems, thermal expansion mismatches can be a serious problem. In the instant case for WSIC 100 and WSIC 200, the substrate material is the same or like the attached chiplets. For example, WSIC 100 or WSIC 200 may comprise silicon, wherein chiplets may also comprise silicon. Here, any thermal mismatches between substrate and chiplets would be negligible.

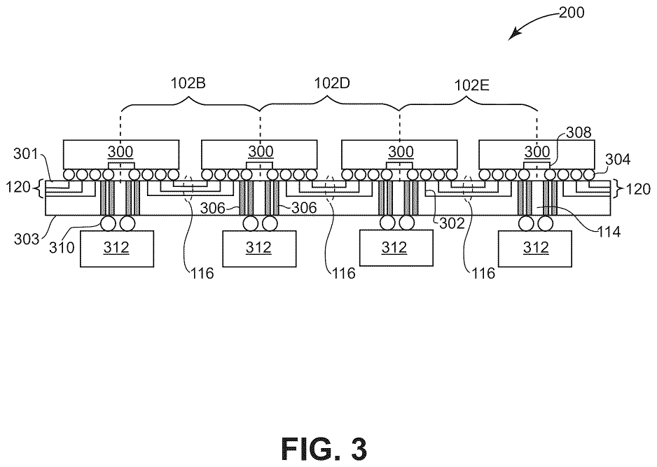

FIG. 3 illustrates a schematic of a cross section of WSIC 200, having an array of chiplets 300 attached to WSIC 200, which provides a substrate for chiplets 300, in accordance with at least one example. In some examples, wire interconnects 120 perform electrical bridging between chiplets 300. Interconnects 120, which are depicted here containing embedded horizonal wires, are grouped into interconnect zones 116. TSVs 302 may be small diameter vertical interconnects that couple individual interconnects 120 to interconnect pads (not shown) on the surface of WSIC 200. Chiplets 300 are solder-bonded to interconnect pads by microbumped solder balls 304 and are interconnected to adjacent chiplets through TSVs 302 and interconnects 120. Reticle fields 102B, 102D, and 102E are shown, where boundaries between adjacent reticle fields are indicated by the dashed vertical lines. Dividing reticle fields are scribe regions 114, coinciding with reticle field boundaries. In the illustrated example, scribe regions 114 are devoid of metallization. Chiplets 300 span across reticle field boundaries and are interconnected by horizonal wire interconnects 120. Adjacent reticle fields (e.g., reticle fields 102B, 102D, and 102E) may be interconnected by internal circuity wiring 308 within individual chiplets 300. As noted above, the employment of interconnect zones 116 and inter-reticle bridging by internal chiplet circuitry enables avoidance of embedded bridge dies, such as EMIB dies, enabling better matching of CTEs of chips with substrate. Inter-reticle bridging by the chiplets 300 also eliminates the need for more coupling of adjacent reticles by reticle stitching, which becomes more difficult to implement as wiring pitch shrinks over large wafers for high bandwidth memories, for example.

In some examples, as shown in FIG. 3, power TSVs 306 may extend vertically between upper surface 301 and lower surface 303 of WSIC 200, and flank scribe regions 114. Other metallization may be present as well, which is not shown here for clarity. Power TSVs 306 may terminate at interconnect pads (not shown) on lower surface 303 of WSIC 200. Such pads may be larger and have a larger pitch (e.g., a millimeter scale) than pads on upper surface 301, which may be on a microbump scale (e.g., having a pitch that is less than 100 microns). In some examples, solder balls 310 may connect power TSVs 306 to power ICs 312. Interconnect pads and I/O TSVs 302 and power TSVs 306 may be part of metallization within quadrants of reticle fields.

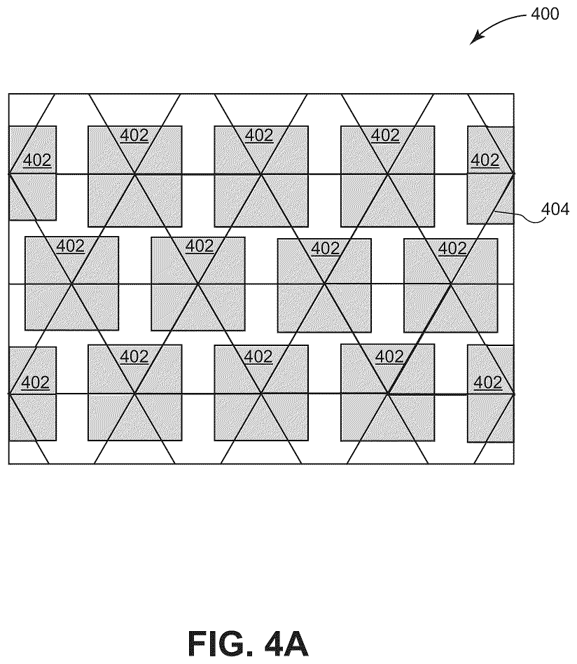

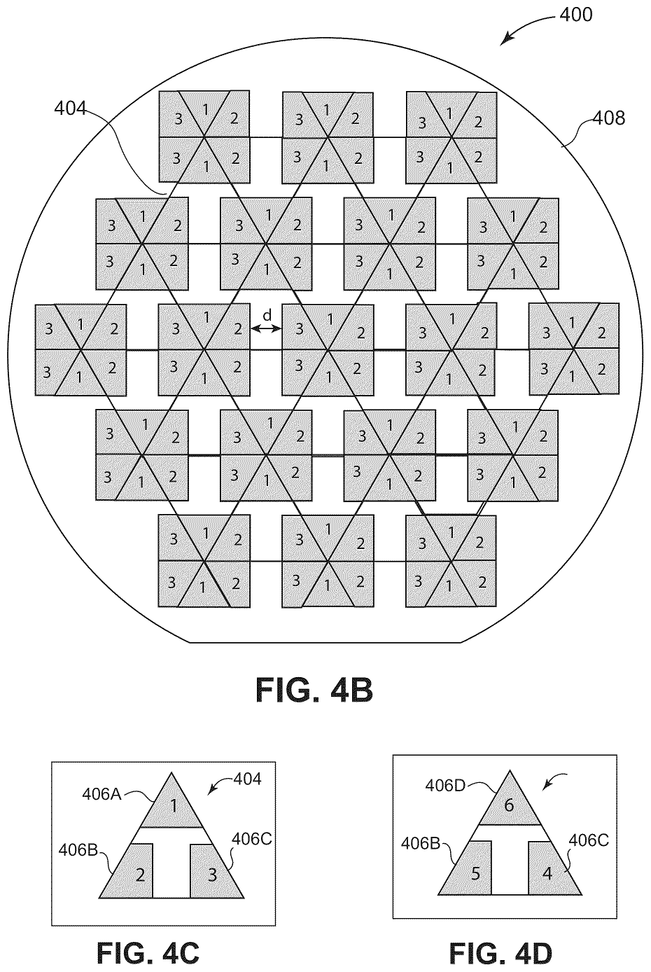

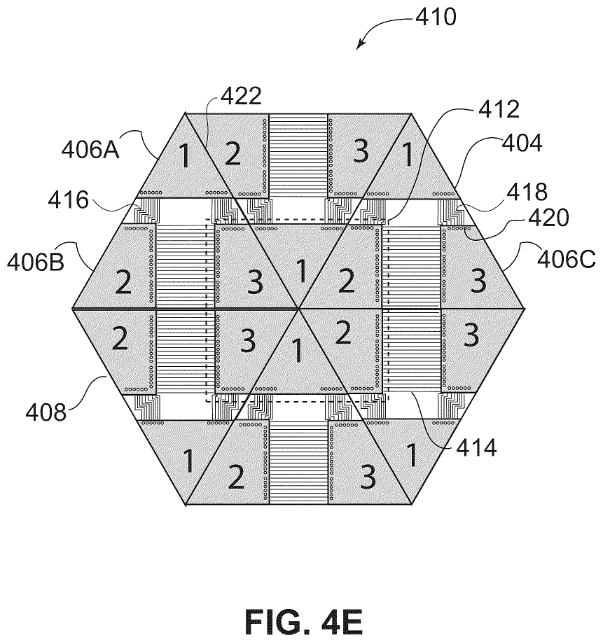

FIG. 4A illustrates a schematic view of a wafer-scale integrated circuit (WSIC) 400, exhibiting a hexagonal reticle geometry, in accordance with at least one example. In the exemplary embodiment, WSIC 400 exhibits a hexagonal distribution of chiplets 402, whereby individual chips 402 are centered at apices of triangular reticles 404. Each chiplet 402 is centered at a center of hexagonally symmetric regions comprising six triangular reticles 404 that fan out from a central point coinciding with the center of each chip 402. In some examples, each individual chip 402 shares six domains, one domain per triangular reticle 404. Each of triangular reticles 404 comprises three domains, as described below.

FIG. 4B illustrates a schematic view of the WSIC 400 shown in FIG. 4A, showing organizational details, in accordance with at least one example. In FIG. 4B, individual domains 406 are marked with numerals 1, 2, and 3 to distinguish one domain from another, and to illustrate that they are repeated within individual triangular reticles 404. In FIG. 4C, an individual triangular reticle 404 comprising three domains 406A, 406B, and 406C is illustrated schematically. Such non-rectangular domains 406A, 406B, and 406C are shown to occur at apices of triangular reticles 404. In some examples, each domain 406A, 406B, and 406C with a triangular reticle 404 may have a metallization pattern (not shown) unique to itself. In some examples, individual domains 406A, 406B, and 406C, corresponding to numerical marks 1, 2, and 3, respectively, are shaped in such a way that when aligned at a hexagonal center, combine to form a rectangular region that is approximately the size and footprint of chips 402. The chip pattern shown in FIG. 4B is repeated across substrate 408 of WSIC 400, which may be circular or rectangular. In the example shown in FIG. 4B, substrate 408 is a circular wafer substrate. The number of chips 402 on WSIC 400 can be increased by decreasing the spacing d between chips 402. Smaller chip size also will increase chip packing.

It is shown in FIG. 4B that six domains comprising two repeats of domains 406A, 406B, and 406C are aligned per chip 402. Domains 406A, 406B, and 406C are numbered 1, 2, and 3, respectively, to distinguish individual domains. The illustrated example shows domains 406 numbered 1, 2, and 3 are repeated twice per triangular reticle 404. In addition, vertically adjacent domains have the same number. Domains 406A, 406B, and 406C may each have different metallization patterns. FIG. 4D shows a configuration having a second triangular reticle 410 comprising domains 406D, 406E, and 406F. Domains 406D-406F may comprise different metallization patterns relative to domains 406A-406C.

FIG. 4E shows a schematic representation of a hexagonal region 410 of WSIC 400, comprising a hexagon comprising six triangle reticles 404, in accordance with at least one example. Triangular reticles 404 are arranged such that a vertex from each abuts five other vertices from the other five triangular reticles 404. A complete chip footprint 412 (delineated by the dashed box) is formed by abutting the six adjacent domains comprising pairs of domains 406A, 406B, and 406C. Neighboring chips are arranged in a greater hexagonal array, whereby FIG. 4E depicts surrounding domains from each neighbor in the greater (chip) array overlapping into hexagonal region 410.

Wafer-level multi-chip substrate interconnection design rules invoked earlier for four-sided symmetry (e.g., WSIC 100 and WSIC 200) may be conserved for the hexagonal symmetry of WSIC 400 as well. A first design rule may be that domains within a triangular reticle 404 may be coupled. FIG. 4E shows an example of in-plane interconnect wire set 414 extending between domains 406B and 406C (e.g., domain 2 coupled to domain 3). In the same example, interconnect wire sets 416 and 418 extend between 406B and 406A and 406C and 406A (e.g., domain 1 coupled respectively to both domain 2 and domain 3). Interconnect wire sets 416 and 418 may be bent as shown to route wires to interconnects pads 420 that are laterally displaced.

Boundaries of triangular reticles 404 may be scribe regions 422, as described for WSIC 100 and WSIC 200, having four-side symmetry. A second design rule may be that reticles remain island-like and electrically isolated. This design rule may also be conserved for hexagonal symmetry. If inter-reticle metallization is present, it may not interconnect domains in adjacent reticles, leaving triangular reticles 404 electrically isolated from one another. Thus, chips may share multiple domains, whereby the domains are not interconnected together through the substrate 408 but may be interconnected together through bridging routing within the individual chips.

Referring once again to FIG. 4B, chips may populate substrate 408 in a hexagonal array pattern without violation of principle design rules 1 and 2 to create WSIC 400. Here, triangular reticles 404 may be stepped across substate 408. In some examples, a single triangle reticle 404 may occupy as standard 800 mm² rectangular reticle field, or two triangle reticles 404, one inverted to form a rhombus, may also fit within a standard reticle field. Edges of substrate 408 may be masked to confine transfer of the triangular reticle patterns in the desired chip layout, confining the lithographic transfer within the boundary of substrate 408, as shown in FIG. 4B.

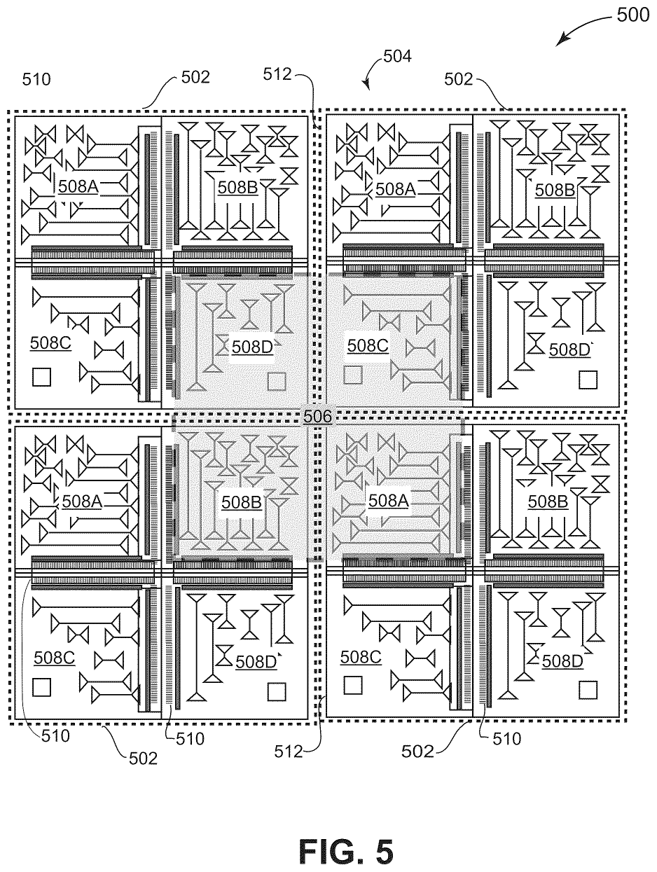

FIG. 5 depicts a schematic representation of multiple metallization patterns within quadrants of reticle fields 502 on WSIC 500, in accordance with at least one example. A portion of a substrate 504 is shown. Each reticle 502, delineated within stippled boxes, is divided into four domains (not referenced here), as described above for WSIC 100 and WSIC 200. Rather, metallization patterns within each of the four domains are referenced as metallization pattern 508A, metallization pattern 508B, metallization pattern 508C and metallization pattern 508D. Metallization patterns comprise traces and pads. It may be understood that each quadrant comprises a metallization pattern. In the illustrative example, each reticle 502 is identical. Chiplet 506 is shown within the dashed box at the center of the reticle array, spanning four adjacent reticles 502. Underlying metallization patterns overlapped by chiplet 506 are, in clockwise order, 508D, 508C, 508A and 508B. These overlapped metallization patterns are visible in the figure through the partially transparent shading of chiplet 506. Quadrants 508A-508D are contributed by separate adjacent reticles 502.

In the illustrative example, metallization patterns 508A-508D contain different patterns. In other examples, particular metallization patterns may repeat in two or more quadrants overlapped by chiplet 506. These options may follow a particular solder ball bumping pattern on chiplet 506 for which WSIC 500 is designed to accommodate. In some examples, multiple chiplets may be assembled on a single wafer scale integrated circuit, therefore metallization patterns may be different across WSIC 500. Metallization patterns 508A-508D comprise bridging interconnects 510 that couple them together within a reticle 502 in accordance with stated design rules. Design rule 2 is conserved here by omitting inter-reticle interconnects through scribe regions 512. Thus, reticles 502 are electrically isolated from one another, as described for WSIC 100 and WSIC 200.

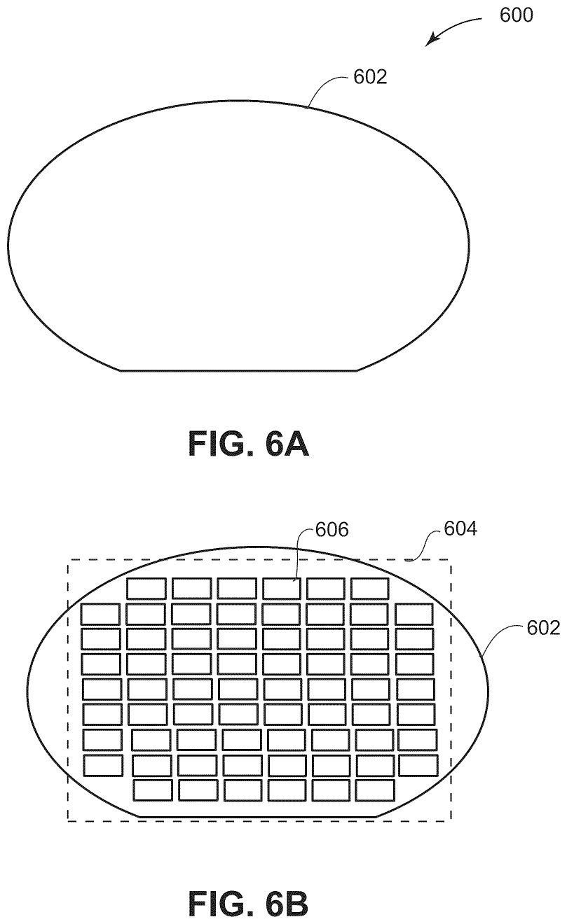

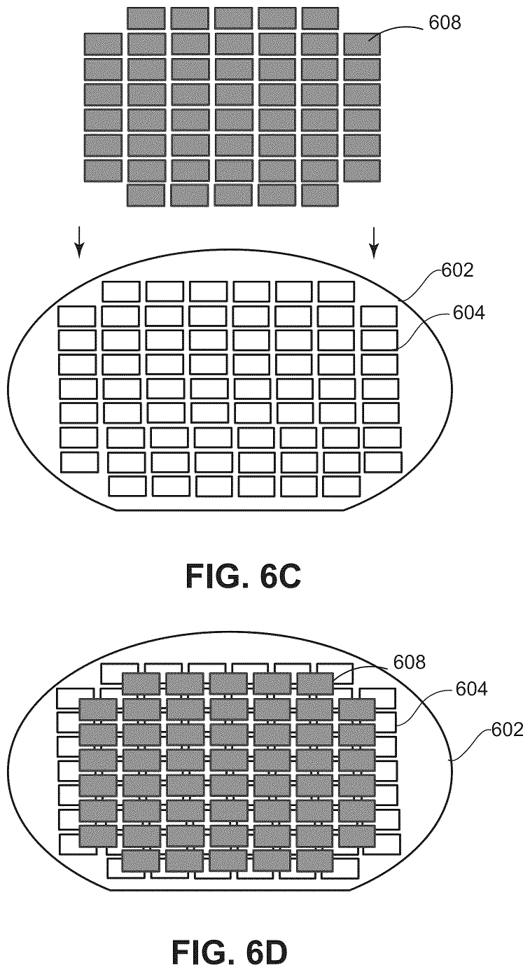

FIGS. 6A-6D illustrate a sequence of structures depicting the evolution of an exemplary assembly process to make a multi-chip wafer-scale integrated circuit, WSIC 600, in accordance with some examples. In FIG. 6A, a bare WSIC substrate wafer 602 is prepared for lithography. Substrate wafer 602 may be standard semiconductive (e.g., silicon) or insulative (e.g., glass, sapphire) wafer having a thickness ranging between 500 to 1000 microns, and a diameter ranging between 100 and 300 mm (or greater). Wafer substrate 602 may be coated with a positive or negative tone photoresist.

In FIG. 6B, a repeating reticle array 604 comprising individual reticles 606 may be transferred lithographically to the substrate by employing a stepping mask aligner, for example. Reticle array 604 may include rows and columns that may fit as many reticles as practical onto substrate wafer 602. For example, a standard reticle size of 26 mm×33 mm may fit up to 78 close-packed reticles, as shown in FIG. 6B onto a 200 mm diameter substrate. Larger substrates may be used for larger close-packed arrays supporting more chips or for more loosely packed chip arrays supporting fewer chips, for example. Such arrays may be large memory arrays of high-bandwidth memory chips, for example. Chips may range in size from a few millimeters to full reticle sizes. Smaller chips may be classified as chiplets, for example, where chip sizes may be under 5 mm on an edge. In these cases, smaller wafers such as 100 mm diameter wafers may be employed as WSIC substrate 602.

Reticles 606 may not be coupled together by means such as reticle stitching or use of bridge dies. Reticle stitching requires provision of lithographically patterned leads extending from reticle boundaries. Such leads are part of the reticle mask design. The leads are connected to metallization within the reticle. Leads extending from adjacent reticles may be overlapped to couple reticles together. For high bandwidth memory devices, the density of leads may be very high, leading to leads having pitches and line widths as small as 2 microns. Reticle stitching in these cases is more difficult as perfect alignment of entire reticles on a stepper mask aligner tool to have good overlap of leads is difficult to achieve. Reticle stitching may limit the bandwidth of wafer-scale multichip memory devices, for example.

Use of bridge dies to couple reticles together can introduce thermal mismatches in the substrate due to embedding of silicon dies into a polymer matrix buildup layer containing a RDL to couple bridge dies to the chips attached to the copper redistribution layer (RDL) layer at the surface of the WSIC substrate (e.g., WSIC substrate 602). Dissimilar CTEs of both silicon and polymer may cause strain between bridge dies and the RDL, tearing the bridge die from the RDL. The effects of thermal mismatch may not be significant at small scale; for example, multichip packages of 2 cm or smaller that contain bridge dies may not have significant displacement of RDL and bridge dies at maximal temperatures. At larger scales however, thermal mismatches become significant and may limit the size and/or bandwidth of wafer-scale multi-chip memory devices. The disclosed WSIC substrates, such as WSIC 100, 200 or 602, comprise uncoupled reticles 604.

In FIGS. 6C and 6D, a schematic representation of placement of a plurality of chips 608 to WSIC substrate wafer 602 is illustrated. Chips 608 may be attached to WSIC substrate wafer 602. Chips 608 may be attached by solder bumping and flip-chip methodologies using pick-and-place methods to populate WSIC substrate 602. Chips 608 may be attached to WSIC substrate 602 in a checker-board fashion, whereby individual chips 608 may overlap four adjacent reticles 604. Thus, chips 608 are aligned by an offset of one half of a reticle in both x and y directions.

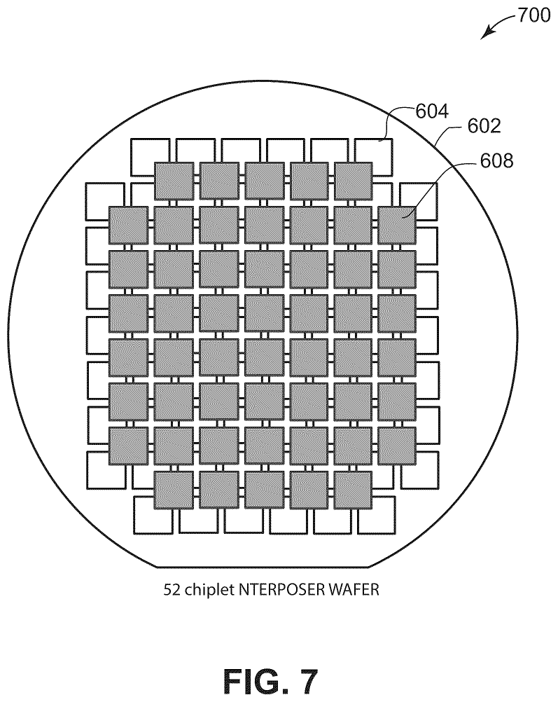

FIG. 7 illustrates a schematic representation of a final stage of assembly of WSIC 600, in accordance with at least one example. WSIC assembly 700 represents a 52-chip interposer wafer as a final assembly of the process flow shown in FIGS. 6A-6D. Chips 608 are attached as a chip array that interpenetrates the array of reticles 604 on WSIC wafer substrate 602. As noted above, chips 608 are offset from the registration of reticles 604 by half a reticle in both x and y directions for each chip to overlap four adjacent reticles. The number of reticles is greater than the number of chips. For example, WSIC assembly 700 is an interposer that accommodates 52 of chips 608. The number of reticles is 68 to accommodate the 52 chips 608. While WSIC wafer substrate 602 may be prepared to mount 52 chips, it may be understood that any number of chips and reticles may be used, depending on chip size. Chips 608 may range in size from chiplet size to full reticle-scale dies. The number of chips that may be assembled on a WSIC wafer follows a progression of the count ratio of chips to reticles. This ratio may approach, but never reach, unity as the chip count increases. The reason for this is that each reticle within the interior of the reticle is occupied by one chip (e.g., four ¼ chips), having a chip-to-reticle ratio of one-to-one. Edge reticles are half occupied by two chips occupying one quadrant each, and corner reticles are one-fourth utilized, being overlapped by one chip occupying one quadrant. At the perimeter of a chip array, edge chips sharing fully occupied interior reticles also share partially occupied edge and corner reticles. A particular layout of reticles on WSIC wafer substrate 602 may have a unique number of edge reticles, thus accommodating a different chip count than another reticle layout on the same substrate.

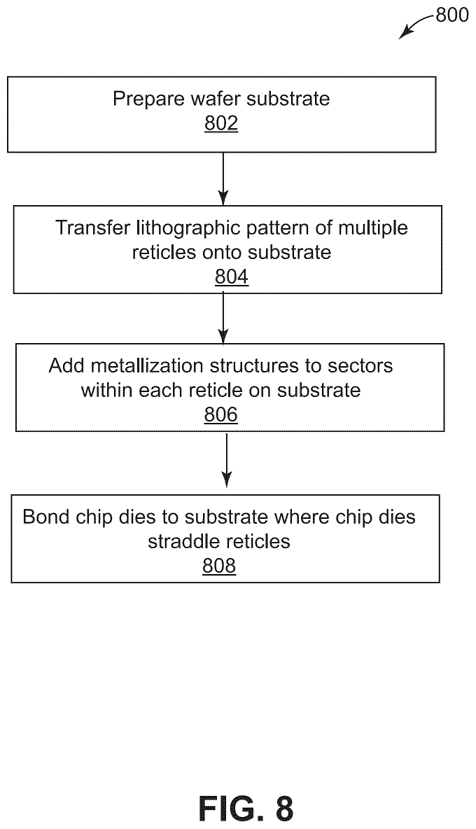

FIG. 8 illustrates a process flow diagram 800 recapping the process flow depicted in FIGS. 6A-6D, in accordance with at least one example. Operations enumerated below follow the progression of steps outlined in FIGS. 6A-6D. At operation 802, a wafer substrate selected for wafer-scale chip assembly is prepared by adding protective layers or preparing liner layers in preparation of copper deposition for metallization structures such as traces and pads. The wafer, such as WSIC wafer substrate 602, may be prepared for service as an interposer, in accordance with some examples. The wafer substrate may be a round substrate, such as WSIC wafer substrate 602, or have a rectangular shape. Wafer substrate sizes may vary. For example, round wafer substrates may have diameters ranging between 100 mm and 300 mm, fitting a standard wafer size scheme. Other examples include wafers having other sizes that may not be standard.

At operation 804, lithographic processing may proceed. Once a wafer substrate is prepared, a photoresist may be deposited on the surface. The photoresist may be a positive tone or negative tone resist. The photoresist may be exposed in a stepper mask aligner, for example, to repeat a reticle pattern across the wafer. Alternatively, a projection scanner may be employed to expose the resist pattern in a step and repeat manner but having higher throughput than a stepper aligner. The reticle pattern may be repeated across the wafer in steps. Multiple reticles may be imaged by creating multiple reticles on the same mask, or by using multiple masks.

At operation 806, the exposed photoresist may be developed to expose openings in the photoresist into which metal (e.g., copper) may be deposited to form metallization patterns on the substrate surface, such as metallization patterns 508A-D shown in FIG. 5. Metallization patterns may be formed by first creating trenches within the substrate surface, and electrodepositing copper within the trenches. A damascene process may be employed, for example. In at least one example, metallization may also be developed as redistribution layers (RDL) at the surface of the substrate, where embedded horizonal interconnect wires (e.g., horizontal interconnects 116 shown in FIG. 3) may be formed. Horizontal interconnects may be embedded in RDL layers using silicon dioxide or polymer as a dielectric, for example.

Surface metallization patterns are divided into four quadrants for four-sided reticle symmetries or into sectors for other reticle geometries (e.g., hexagonal reticle pattern 404 shown in FIGS. 4A and 4B). An example of surface metallization is shown in FIG. 5 for WSIC substrate 500, where each quadrant has a metallization pattern 508A-508D. Surface metallization may include traces and interconnect pads for chip bonding.

At operation 808, chips may be bonded by flip-chip methodologies where chips are solder bumped and flipped 180 degrees to bond onto pads formed on the substrate. As described above, interior reticles of a reticle array may share four chips, where each chip is bonded to a quadrant within the reticle, as shown in FIG. 7. Edge reticles may share two chips, leaving two quadrants unoccupied, and corner reticles may only have one quadrant occupied by one chip. The reticles may be coupled together through internal circuitry within each chip straddling reticle boundaries, whereas chips are coupled together within a reticle through intra-reticle horizontal interconnects.

Here, “device,” “node,” or “unit” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus, which comprises the device.

Here, “connected” or “connection” means a direct connection, such as electrical, mechanical, or magnetic connection between the things that are connected, without any intermediary devices.

Here, “coupled” means a direct or indirect connection, such as a direct electrical, mechanical, or magnetic connection between the things that are connected or an indirect connection, through one or more passive or active intermediary devices.

Here, “adjacent” generally refers to a position of a thing being next to (e.g., immediately next to or close to with one or more things between them) or adjoining another thing (e.g., abutting it).

Here, “signal lines” or “wires” generally refers to conductive pathways that facilitate transmission of data and control signals between different components (e.g., chiplets, processing cores or multi-core processors). Each signal line or wire can represent a single bit of information or can be grouped together to form a bus to transmit multiple bits simultaneously.

Here, “circuit” or “module” may refer to one or more passive and/or active components that are arranged to cooperate with one another to provide a desired function.

Here, “signal” may refer to at least one current signal, voltage signal, magnetic signal, or data/clock signal. The meaning of “a,” “an,” and “the” include plural references. The meaning of “in” includes “in” and “on.”

Here, “analog signal” generally refers to any continuous signal for which the time varying feature (variable) of the signal is a representation of some other time varying quantity, i.e., analogous to another time varying signal.

Here, “digital signal” generally refers to a physical signal that is a representation of a sequence of discrete values (a quantified discrete-time signal), for example of an arbitrary bit stream, or of a digitized (sampled and analog-to-digital converted) analog signal.

Here, “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e., scaling down, or scaling up respectively) of a signal frequency relative to another parameter, for example, power supply level.

Here, “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

Unless otherwise specified the use of the ordinal adjectives “first,” “second,” and “third, etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device.

Reference in the specification to “an example,” “one example,” “some examples,” or “other examples” means that a particular feature, structure, or characteristic described in connection with the examples is included in at least some examples, but not necessarily all examples. The various appearances of “an example,” “one example,” or “some examples” are not necessarily all referring to the same examples. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more examples. For example, a first example may be combined with a second example anywhere the particular features, structures, functions, or characteristics associated with the two examples are not mutually exclusive.

While the disclosure has been described in conjunction with specific examples thereof, many alternatives, modifications and variations of such examples will be apparent to those of ordinary skill in the art considering the foregoing description. The examples of the disclosure are intended to embrace all such alternatives, modifications, and variations as to fall within the broad scope of the appended claims.

In addition, well-known power/ground connections to IC chips and other components may or may not be shown within the presented figures, for simplicity of illustration and discussion, and so as not to obscure the disclosure. Further, arrangements may be shown in block diagram form to avoid obscuring the disclosure, and because specifics with respect to implementation of such block diagram arrangements are highly dependent upon the platform within which the present disclosure is to be implemented (i.e., such specifics should be well within purview of one skilled in the art). Where specific details (e.g., circuits) are set forth to describe examples of the disclosure, it should be apparent to one skilled in the art that the disclosure can be practiced without, or with variation of, these specific details. The description is thus to be regarded as illustrative instead of limiting.

The structures of various examples described herein can also be described as method(s) of forming those structures or apparatuses, and method(s) of operation of these structures or apparatuses. The following examples are provided that illustrate the various examples of the disclosure. The examples can be combined with other examples. As such, various examples can be combined with other examples without changing the scope of the invention.

Example 1 is a multi-reticle integrated circuit structure, comprising: a substrate comprising a surface; and an array of lithographically-patterned regions distributed on the surface of the substrate, wherein: ones of the lithographically-patterned regions comprise two or more domains; each of the two or more domains comprise one of one or more metallization structure patterns; each domain of the two or more domains is interconnected to at least one adjacent domain by a plurality of embedded interconnects coupled to a first metallization structure pattern within the at least one adjacent domain; the plurality of embedded interconnects extends laterally between adjacent domains of the two or more domains; and the ones of the lithographically-patterned regions includes a first lithographically-patterned region and a second lithographically-patterned region, wherein an IC die of a plurality of IC dies is bonded to at least a first domain of the two or more domains in the first lithographically-patterned region and to a second domain of the two or more domains in the second lithographically-patterned region, wherein the second domain is adjacent to the first domain.

Example 2 is a multi-reticle integrated circuit structure according to any example herein, in particular example 1, wherein ones of the lithographically-patterned regions have at least three sides.

Example 3 is a multi-reticle integrated circuit structure according to any example herein, in particular example 2, wherein a scribe region extends along each of the at least three sides.

Example 4 is a multi-reticle integrated circuit structure according to any example herein, in particular example 3, wherein the lithographically-patterned regions are distinct from one another.

Example 5 is a multi-reticle integrated circuit structure according to any example herein, in particular example 1, wherein the surface is a first surface, wherein the plurality of embedded interconnects is distributed within the substrate between the first surface and an opposing second surface.

Example 6 is a multi-reticle integrated circuit structure according to any example herein, in particular example 5, wherein a plurality of TSVs extends from the first surface to the opposing second surface of the substrate within each domain of the two or more domains.

Example 7 is a multi-reticle integrated circuit structure according to any example herein, in particular example 1, wherein the substrate comprises an interposer, and wherein the one or more metallization structure patterns are in or on the interposer.

Example 8 is a multi-reticle integrated circuit substrate, comprising: a first surface and an opposing second surface; and an array of reticles distributed on the first surface, wherein: each one of the reticles comprises four quadrants; and an IC die is bonded to at least a first quadrant of a first reticle and to a second quadrant of a second reticle, wherein the second quadrant is adjacent to the first quadrant.

Example 9 is a multi-reticle integrated circuit substrate according to any example herein, in particular example 8, wherein: each of the four quadrants of an individual reticle comprises one metallization pattern; and each quadrant is interconnected to at least two of the four quadrants within a reticle.

Example 10 is a multi-reticle integrated circuit substrate according to any example herein, in particular example 9, wherein a first metallization pattern of the first quadrant of the reticle is coupled to a second metallization pattern of the second quadrant of the reticle by wires extending on the first surface.

Example 11 is a multi-reticle integrated circuit substrate according to any example herein, in particular example 9, wherein a first metallization pattern of the first quadrant of the reticle is coupled to a second metallization pattern of the second quadrant of the reticle of wires extending between the first surface and the opposing second surface.

Example 12 is a multi-reticle integrated circuit substrate according to any example herein, in particular example 9, wherein the individual reticle comprises four unique metallization patterns including a first metallization pattern, a second metallization pattern, a third metallization pattern, and a fourth metallization pattern.

Example 13 is a multi-reticle integrated circuit substrate according to any example herein, in particular example 12, wherein the first quadrant comprises the first metallization pattern, wherein the second quadrant comprises the second metallization pattern, wherein the four quadrants comprise a third quadrant comprising the third metallization pattern, and a fourth quadrant comprising the fourth metallization pattern.

Example 14 is a multi-reticle integrated circuit substrate according to any example herein, in particular example 8, wherein two adjacent reticles of the array of reticles are separated by a scribe line extending along a boundary between the two adjacent reticles, and wherein the two adjacent reticles are electrically isolated from one another.

Example 15 is a wafer-level integrated circuit comprising: a wafer substrate; an array of lithographically-patterned regions distributed on the wafer substrate, wherein: one of the lithographically-patterned regions comprise two or more domains, wherein the two or more domains are non-contiguous; each of the two or more domains comprise one of one or more metallization structure patterns; each domain of the two or more domains is interconnected to at least one adjacent domain by a plurality of embedded interconnects coupled to a first metallization structure pattern within the at least one adjacent domain; and the plurality of embedded interconnects extends laterally between adjacent domains of the two or more domains; and a plurality of IC dies, wherein each IC die of the plurality of IC dies is bonded to at least a first domain of the two or more domains in a first lithographically patterned region and to a second domain of the two or more domains in a second lithographically patterned region, wherein the second domain is adjacent to the first domain.

Example 16 is a wafer-level integrated circuit according to any example herein, in particular example 15, wherein each IC die is thermocompression bonded, solder bonded, laser-assisted bonded or hybrid bonded to the first domain and to the second domain.

Example 17 is a wafer-level integrated circuit according to any example herein, in particular example 15, wherein each IC die of the plurality of IC dies is electrically coupled to an adjacent IC die by the plurality of embedded interconnects.

Example 18 a wafer-level integrated circuit according to any example herein, in particular example 15, wherein each IC die of the plurality of IC dies overlaps two or more adjacent domains, wherein the two or more adjacent domains are electrically isolated from one another.

Example 19 is a method for making a wafer-level interposer comprising: coating a wafer substrate with a photoresist; stepping a lithographic mask reticle metallization pattern across the wafer substrate to create an array of lithographically patterned regions in the photoresist, wherein the lithographic mask reticle metallization pattern comprises two or more domains; developing the lithographic mask reticle metallization pattern in the photoresist; creating the array of lithographically patterned regions on the wafer substrate, wherein: the array of lithographically patterned regions is distributed on the wafer substrate, each domain of the two or more domains is interconnected to at least one adjacent domain by a plurality of embedded interconnects coupled to a first metallization structure pattern within the at least one adjacent domain; and the plurality of embedded interconnects extends laterally between adjacent domains of the two or more domains; and wherein the method further comprises: bonding each IC die of a plurality of IC dies to at least a first domain of the two or more domains in a first lithographically patterned region and to a second domain of the two or more domains in a second lithographically patterned region, wherein the second domain is adjacent to the first domain.

Example 20 is a method for making a wafer-level interposer according to any example herein, in particular example 19, wherein stepping the lithographic mask reticle metallization pattern across the wafer substrate comprises offsetting the array of lithographically patterned regions from one another by a scribe region between adjacent lithographically patterned regions.

Example 21 is a method for making a wafer-level interposer according to any example herein, in particular example 19 wherein an individual lithographically patterned region of the array of lithographically patterned regions comprises a mask reticle metallization pattern, and wherein a scribe region is within a gap between adjacent lithographically patterned regions.

Example 22 is a method for making a wafer-level interposer according to any example herein, in particular example 21, wherein the plurality of embedded interconnects is formed between the adjacent domains of the two or more domains, wherein the plurality of embedded interconnects is coupled to the first domain of the two or more domains and to the second domain of the two or more domains.

Example 23 is a method for making a wafer-level interposer according to any example herein, in particular example 19, wherein bonding each IC die of a plurality of IC dies to at least the first domain of the two or more domains comprises thermocompression bonding each IC die, solder bonding each IC die, laser assisted bonding each IC die or hybrid bonding each IC die to the first domain and the second domain.

What is claimed is:

1. A multi-reticle integrated circuit structure, comprising:
a substrate comprising a surface; and
an array of lithographically-patterned regions distributed on the surface of the substrate, wherein:
ones of the lithographically-patterned regions comprise two or more domains;
each of the two or more domains comprise one of one or more metallization structure patterns;
each domain of the two or more domains is interconnected to at least one adjacent domain by a plurality of embedded interconnects coupled to a first metallization structure pattern within the at least one adjacent domain;
the plurality of embedded interconnects extends laterally between adjacent domains of the two or more domains; and
the ones of the lithographically-patterned regions includes a first lithographically-patterned region and a second lithographically-patterned region, wherein an IC die of a plurality of IC dies is bonded to at least a first domain of the two or more domains in the first lithographically-patterned region and to a second domain of the two or more domains in the second lithographically-patterned region, wherein the second domain is adjacent to the first domain.

2. The multi-reticle integrated circuit structure of claim 1, wherein ones of the lithographically-patterned regions have at least three sides.

3. The multi-reticle integrated circuit structure of claim 2, wherein a scribe region extends along each of the at least three sides.

4. The multi-reticle integrated circuit structure of claim 3, wherein the lithographically-patterned regions are distinct from one another.

5. The multi-reticle integrated circuit structure of claim 1, wherein the surface is a first surface, wherein the plurality of embedded interconnects is distributed within the substrate between the first surface and an opposing second surface.

6. The multi-reticle integrated circuit structure of claim 5, wherein a plurality of TSVs extends from the first surface to the opposing second surface of the substrate within each domain of the two or more domains.

7. The multi-reticle integrated circuit structure of claim 1, wherein the substrate comprises an interposer, and wherein the one or more metallization structure patterns are in or on the interposer.

8. A multi-reticle integrated circuit substrate, comprising:
a first surface and an opposing second surface; and
an array of reticles distributed on the first surface, wherein:
each one of the reticles comprises four quadrants; and
an IC die is bonded to at least a first quadrant of a first reticle and to a second quadrant of a second reticle, wherein the second quadrant is adjacent to the first quadrant.

9. The multi-reticle integrated circuit substrate of claim 8, wherein:
each of the four quadrants of an individual reticle comprises one metallization pattern; and
each quadrant is interconnected to at least two of the four quadrants within a reticle.

10. The multi-reticle integrated circuit substrate of claim 9, wherein a first metallization pattern of the first quadrant of the reticle is coupled to a second metallization pattern of the second quadrant of the reticle by wires extending on the first surface.

11. The multi-reticle integrated circuit substrate of claim 9, wherein a first metallization pattern of the first quadrant of the reticle is coupled to a second metallization pattern of the second quadrant of the reticle of wires extending between the first surface and the opposing second surface.

12. The multi-reticle integrated circuit substrate of claim 9, wherein the individual reticle comprises four unique metallization patterns including a first metallization pattern, a second metallization pattern, a third metallization pattern, and a fourth metallization pattern.

13. The multi-reticle integrated circuit substrate of claim 12, wherein the first quadrant comprises the first metallization pattern, wherein the second quadrant comprises the second metallization pattern, wherein the four quadrants comprise a third quadrant comprising the third metallization pattern, and a fourth quadrant comprising the fourth metallization pattern.

14. The multi-reticle integrated circuit substrate of claim 8, wherein two adjacent reticles of the array of reticles are separated by a scribe line extending along a boundary between the two adjacent reticles, and wherein the two adjacent reticles are electrically isolated from one another.

15. A wafer-level integrated circuit comprising:
a wafer substrate;
an array of lithographically-patterned regions distributed on the wafer substrate, wherein:
one of the lithographically-patterned regions comprise two or more domains, wherein the two or more domains are non-contiguous;
each of the two or more domains comprise one of one or more metallization structure patterns;
each domain of the two or more domains is interconnected to at least one adjacent domain by a plurality of embedded interconnects coupled to a first metallization structure pattern within the at least one adjacent domain; and
the plurality of embedded interconnects extends laterally between adjacent domains of the two or more domains; and
a plurality of IC dies, wherein each IC die of the plurality of IC dies is bonded to at least a first domain of the two or more domains in a first lithographically patterned region and to a second domain of the two or more domains in a second lithographically patterned region, wherein the second domain is adjacent to the first domain.

16. The wafer-level integrated circuit of claim 15, wherein each IC die is thermocompression bonded, solder bonded, laser-assisted bonded or hybrid bonded to the first domain and to the second domain.

17. The wafer-level integrated circuit of claim 15, wherein each IC die of the plurality of IC dies is electrically coupled to an adjacent IC die by the plurality of embedded interconnects.

18. The wafer-level integrated circuit of claim 15, wherein each IC die of the plurality of IC dies overlaps two or more adjacent domains, wherein the two or more adjacent domains are electrically isolated from one another.

19. A method for making a wafer-level interposer comprising:
coating a wafer substrate with a photoresist;
stepping a lithographic mask reticle metallization pattern across the wafer substrate to create an array of lithographically patterned regions in the photoresist, wherein the lithographic mask reticle metallization pattern comprises two or more domains;
developing the lithographic mask reticle metallization pattern in the photoresist;
creating the array of lithographically patterned regions on the wafer substrate, wherein:
the array of lithographically patterned regions is distributed on the wafer substrate,
each domain of the two or more domains is interconnected to at least one adjacent domain by a plurality of embedded interconnects coupled to a first metallization structure pattern within the at least one adjacent domain; and
the plurality of embedded interconnects extends laterally between adjacent domains of the two or more domains; and wherein the method further comprises:
bonding each IC die of a plurality of IC dies to at least a first domain of the two or more domains in a first lithographically patterned region and to a second domain of the two or more domains in a second lithographically patterned region, wherein the second domain is adjacent to the first domain.

20. The method of claim 19, wherein stepping the lithographic mask reticle metallization pattern across the wafer substrate comprises offsetting the array of lithographically patterned regions from one another by a scribe region between adjacent lithographically patterned regions.

21. The method of claim 19 wherein an individual lithographically patterned region of the array of lithographically patterned regions comprises a mask reticle metallization pattern, and wherein a scribe region is within a gap between adjacent lithographically patterned regions.

22. The method of claim 21, wherein the plurality of embedded interconnects is formed between the adjacent domains of the two or more domains, wherein the plurality of embedded interconnects is coupled to the first domain of the two or more domains and to the second domain of the two or more domains.

23. The method of claim 19, wherein bonding each IC die of a plurality of IC dies to at least the first domain of the two or more domains comprises thermocompression bonding each IC die, solder bonding each IC die, laser assisted bonding each IC die or hybrid bonding each IC die to the first domain and the second domain.
